(19) United States
(12) Patent Application Publication
(10) Pub. No.: US 2013/0064974 A1
(43) Pub. Date: Mar. 14, 2013

(54) METHODS AND APPARATUSES FOR CONVERTING EXPANDED POLYSTYRENE INTO A RIGID MATERIAL

(71) Applicant: Duncan Edward Meyers, Gresham, OR (US)

(72) Inventor: Duncan Edward Meyers, Gresham, OR (US)

(21) Appl. No.: 13/229,605

(22) Filed: Sep. 9, 2011

(51) Int. Cl. C23C 16/00; C08J 9/228

(52) U.S. Cl. 427/248.1; 521/56; 521/55

(57) ABSTRACT

Methods and apparatuses for converting expanded polystyrene into a rigid material are disclosed herein. The methods of modifying EPS herein generally include placing EPS workload into a pressurized chamber and applying heat and pressure through a gas. The application of heat and pressure is held for a determined amount of time, the pressure of the internal chamber is then lowered below atmospheric pressure and a hot or cool step is administered. The resulting CPS product can be modified in a multiple number of ways depending on the desired end product.

### FIELD OF THE INVENTION

The embodiments herein relate to methods and apparatuses for converting expanded polystyrene into a rigid material useful in numerous commercial industries, non-exclusively including construction, automotive, and aeronautics.

### BACKGROUND

Expanded polystyrene, also called “EPS” or styrofoam, is an affordable, light weight thermoplastic substance, commonly used to pack food, drinks, in addition to fragile and deformable goods. Typical EPS products are approximately 95-98% air and only about 2-5% polystrene. EPS can be difficult to recycle and costly to transport, and thus presents a significant environmental problem. EPS recycling and disposal is often focused on volume reduction processes and apparatuses such as EPS densifiers. In general, EPS densifiers incorporate high compression to compact the EPS into densified logs and can be easily transported for disposal or for further processing such as extrusion pelletizing.

One example of an EPS densifier is disclosed in U.S. Pat. No. 5,664,491 to Maki et al., which is hereby incorporated by reference in its entirety. Unfortunately, and as shown in FIG. 4A, applying high pressure from mechanical means such as those disclosed by Maki et al., can cause the individual beads that make up EPS to collapse and lose their structural integrity. Compromising the structural integrity of EPS in this fashion is not desirable if a user desires to reuse the EPS for structural, strengthening, or support end purposes.

Accordingly, an objective of the teachings herein to overcome the disadvantageous of current methods used to recycle or dispose of EPS to allow for compressed polystyrene or CPS products that can be utilized for support, structural, and strengthening ends.

### SUMMARY OF THE INVENTION

Preferred embodiments are directed to processes for converting expanded polystyrene (EPS) into a compressed material, comprising: placing an EPS workload into a pressurized chamber; increasing the temperature within the chamber; increasing the pressure within the chamber by introducing a gaseous material into the chamber such that the pressure within the chamber does not exceed 500 psi to create a compressed polystyrene material from the EPS workload.

### BRIEF DESCRIPTION OF THE DRAWINGS

It will be appreciated that the drawings are not necessarily to scale, with emphasis instead being placed on illustrating the various aspects and features of embodiments of the invention, in which:

FIG. 1 is a flow chart depicting different methods of making compressed EPS products

FIG. 2 is an exemplary type of pressurized chamber.

FIG. 3 is a second exemplary type of pressurized chamber.

FIG. 4A depicts a prior art method of high pressure mechanical force compromising the structural integrity of the EPS beads.

FIG. 4B depicts a lower pressure compression method that does not compromise the structural integrity of the EPS beads like the prior art.

FIG. 5 is a perspective view of EPS being broken down into smaller chunks.

FIG. 6 is a perspective view of EPS being extruded into logs.

FIG. 7 is a perspective view of an EPS log being moved along a conveyor belt.

FIGS. 8A-8C depict an EPS log being cut.

FIG. 9 depicts a processing system configured to convert EPS to a rigid material.

### DETAILED DESCRIPTION OF THE ILLUSTRATED EMBODIMENTS

Embodiments of the present invention are described below. It is, however, expressly noted that the present invention is not limited to these embodiments, but rather the intention is that modifications that are apparent to the person skilled in the art and equivalents thereof are also included.

The methods herein, in general are directed to three general embodiments of making compressed EPS derived products including, wallboard, and rock. In general the embodiments herein involve placing EPS material to be compressed into a chamber where increased temperature and pressure is applied for a certain period of time, a partial vacuum is then created where the internal gaseous pressure is less than atmospheric pressure, followed by a hot or cool preparation step.

### CPS Wallboard

According to preferred embodiments, methods of making compressed polystyrene (CPS) wallboard from EPS are provided herein. CPS wallboard can be utilized as a substitute for any traditional wallboard such as gypsum board, and plasterboard drywall. In general used or waste EPS 10 can be gathered, such as EPS used for shipping containers or portable coolers, non-exclusively including EPS beads or peanuts, for example. Waste EPS 10 can be placed into the hopper 20 of a grinder 30, or a pre-breaker. The hopper 20 is designed to direct the waste EPS 10 to cutting elements 40a and 40b which break up the waste EPS 10 into smaller, uniform, or similar sized chunks of EPS 50. As one example, the EPS chunks 50 can be approximately between 2-3 inches in length. EPS beads can also be substituted for the EPS chunks 50 for the teachings herein. Any suitable cutting means can be used to break up the waste EPS 10, such as rotating rollers having sharp protrusions, or mechanical teeth like those used in paper shredders. The cut EPS chunks 50 can then be transported, such as being blown through a hose 52, to a chamber to be extruded. FIG. 6 depicts a chamber where an auger 60 applies pressure to the EPS chunks 50 and extrudes them through a die 70 having a cutout 80 configured to give the extruded EPS the desired cross-sectional shape, such as that of a rectangle, or more specifically a continuous sheet, for example. Any suitable means for extrusion can be used to form the EPS log 90, non-exclusively including direct and indirect extrusion, the use of one or more augers or rams, hydraulic or mechanical drives, and variable or hydrostatic load application. In addition, the extrusion can be performed in either a vertical or horizontal direction.

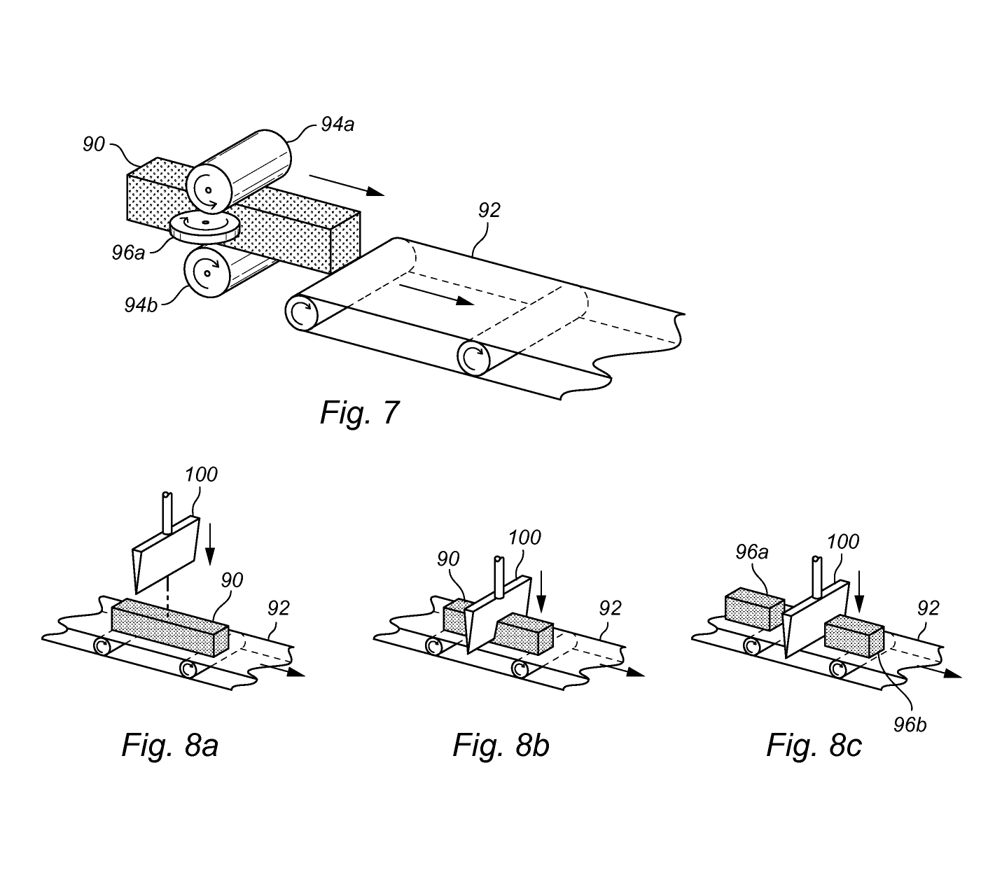

According to preferred embodiments, the extruded EPS log 90 can be flexible and has the potential to lose its shape if mishandled. Accordingly, light pressure can be applied at least intermittently, if not continuously through processing, such as before and after a conveyor belt. As an example, light pressure means, such as one or more guide wheels can be used in conjunction with a conveyor belt 92 to apply slight force on the EPS log 90, such that its form is protected and maintained or substantially so during transport to the next step in the process. More specifically, FIG. 7 shows multiple guide wheels that can be used to maintain the shape of the EPS log 90. A top and/or bottom guide wheel 94a and 94b can be used to apply vertical pressure and one or more side guide wheels can be used to apply horizontal pressure. While FIG. 7 depicts one side wheel 96a a second side wheel can likewise be used on the opposite side of the EPS log 90.

Depending on the size of the pressurized chamber in the next step and the users' goals, the EPS log 90 can be cut or further modified before being compressed. As one example a cutting blade 100 can be positioned above the conveyor belt 92 such as to cut the EPS log 90 widthwise into halves, thirds, or other smaller pieces. More specifically, FIG. 8A shows an EPS log 90 prior to being cut, FIG. 8B shows the EPS log 90 being cut by the blade 100 to form two sheets 96a and 96b shown in FIG. 8C. The EPS log 90 can also be cut lengthwise into halves, thirds, or other smaller pieces, depending on the users' goals. The EPS log 90 can also or alternatively be further shaped through another extrusion process or cutting, for example, before being placed into the pressurized chamber.

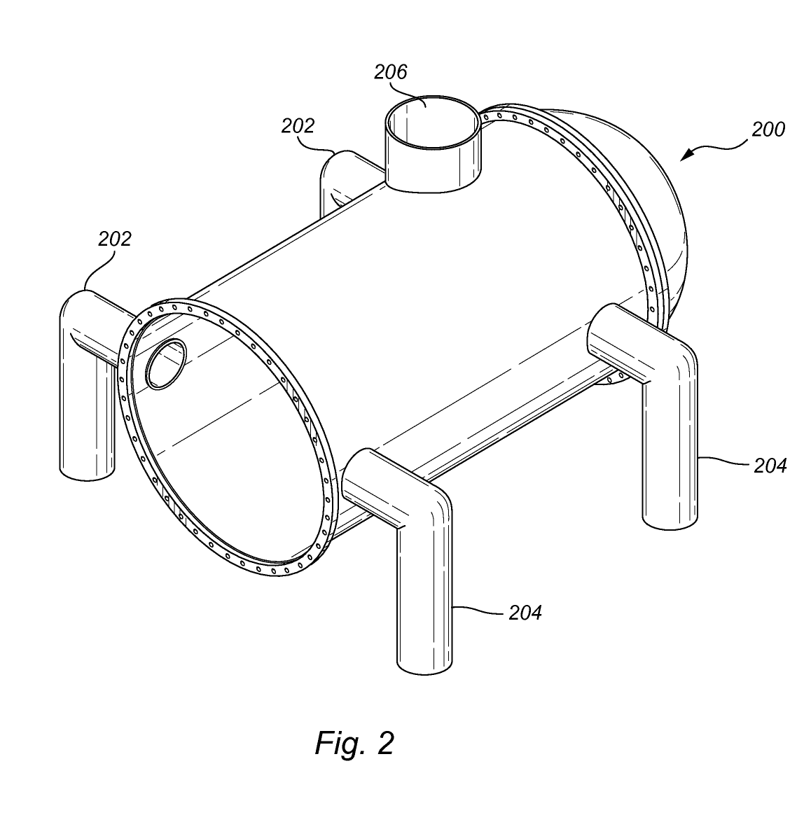

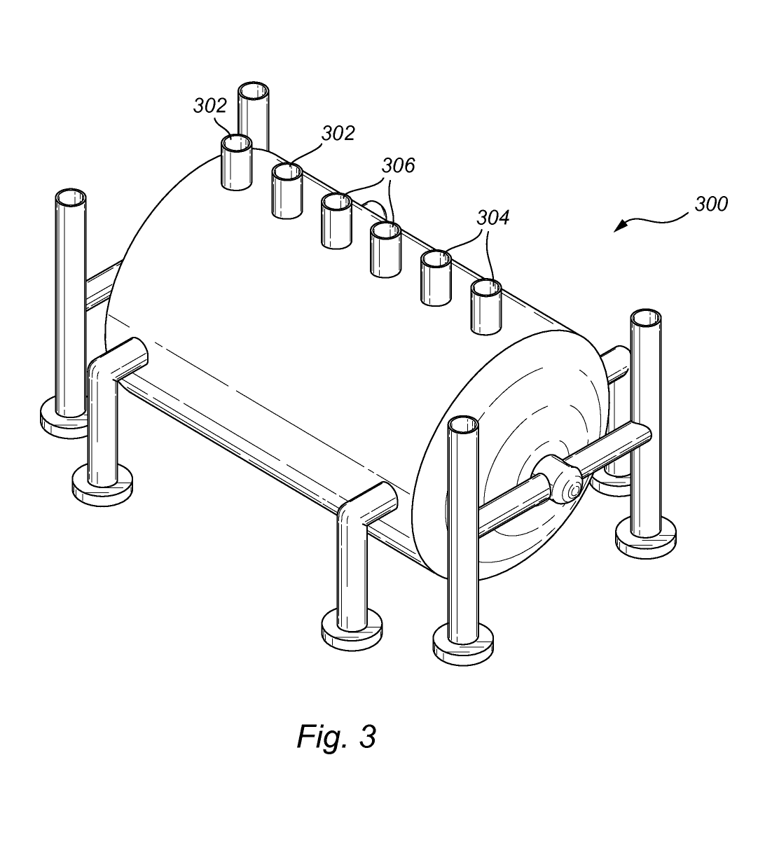

After optional modification, either the extruded EPS log 90 or sections thereof (e.g., 96a and 96b) can be positioned into a pressurized chamber, such as 200 in FIG. 2 or 300 in FIG. 3. Depending on the size of the EPS log 90 sheets 96a and 96b or pieces, and the chamber, one or more EPS materials can be positioned into the chamber to define the workload. The chamber can include racks or other organizational means for allowing multiple EPS materials to be inserted at one time. According to certain embodiments, 25, 50, 75, 100, or more EPS materials can be placed into a single chamber at once.

Any suitable pressurized chamber can be used with the teachings herein but preferably include internal pressure and temperature control and the ability to lower the internal gaseous pressure to below atmospheric pressure. As an example, FIG. 2 shows a pressure chamber 200 having two inlets 202 for steam or an inert gas and two outlets 204. An emergency blow-off 206 can also be utilized with the teachings herein. The chamber 200 shown in FIG. 2 is without a lid to provide a partial view of the inner chamber. While not shown the chamber 200 includes a lid that can be opened to insert the EPS workload and closed to seal the chamber. FIG. 3 depicts another embodiment of a pressurized chamber 300 having two inlets 302 for steam or an inert gas, two outlets 304, two emergency blow-offs 306. More specifically, preferred pressurized chambers to be used with the embodiments herein preferably can include means for heating, pressurizing, circulating gas, cooling the internal workload. Suitable pressurized chambers include autoclaves, and the like, for example.

Once the EPS workload is positioned within the chamber, holding means can be utilized, such as hydraulic cams to hold the workload in a particular position. The holding means are configured not to exert pressure sufficient enough to destroy the three-dimensional structure of the polystyrene beads.

With the EPS workload placed into the pressurized chamber and the chamber sealed, the chamber's temperature is preferably raised to 230° F. and pressurized to 15 psi. Variations can include an initial temperature of between 190-250° F. and a pressure between 0.1-15 psi. It is preferred that the pressurization is done by introducing and circulating a gas, such as an inert gas selected from: Helium (He), Neon (Ne), Argon (Ar), Krypton (Kr), Xenon (Xe), Radon (Rn), Sulfur hexafluoride (SF6), and Nitrogen (N2). According to more specific embodiments, the gas is a heated gas and can thus provide both simultaneous temperature and pressure increase within the chamber. Alternatively steam from water can be used to raise the temperature and pressure within the chamber. Methods of utilizing physical, machine force for pressurizing, such as using a heated press are expressly excluded with the teachings herein.

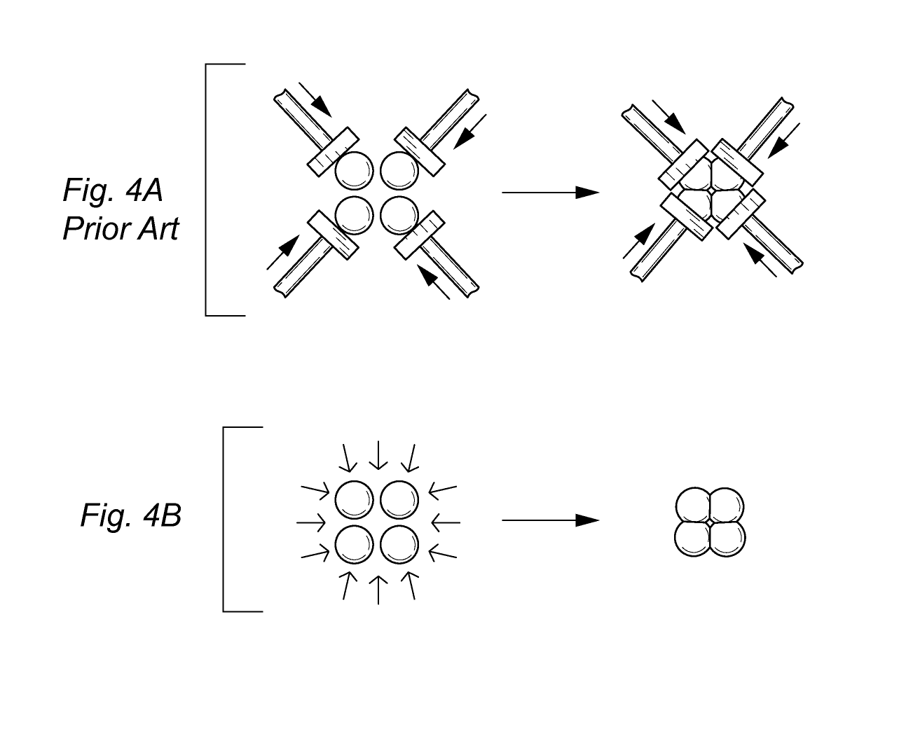

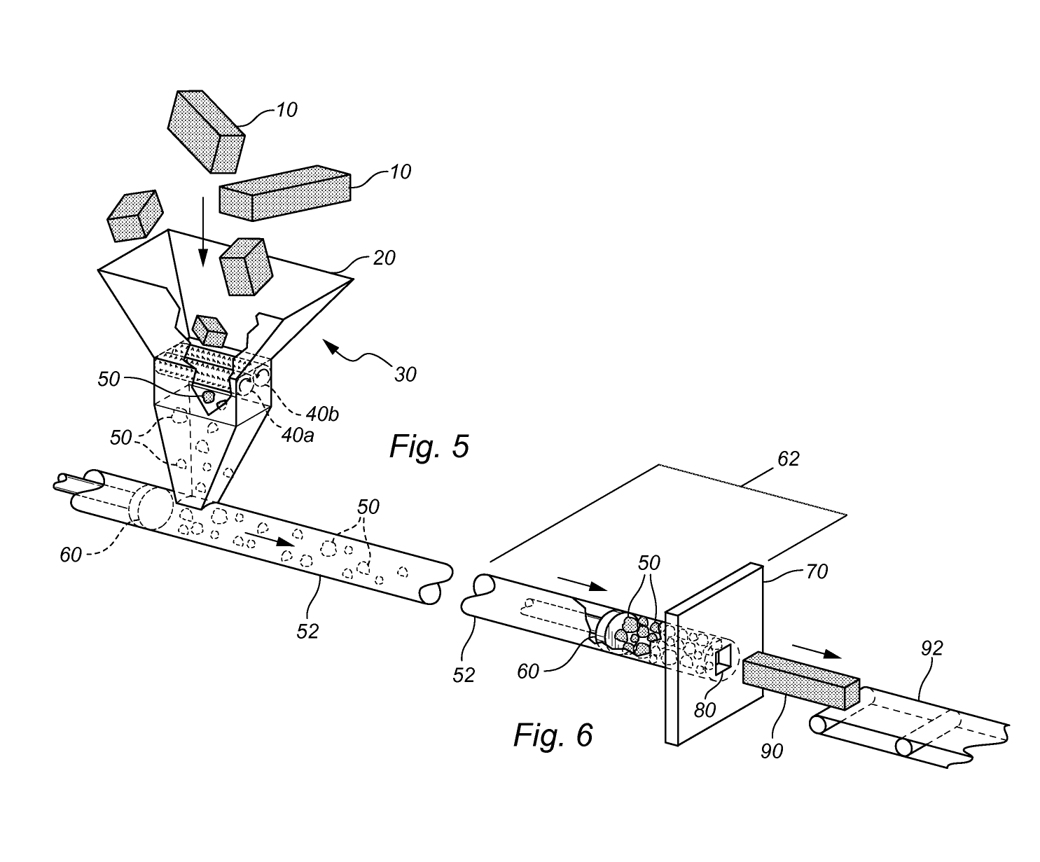

Means for heating the EPS workload within the pressurized chamber can be done using any suitable way, including steam, heated gas, heating elements, and electrical means, for example. Preferably the heating means are provided by injection of a heated, inert gas. The pressurized chamber preferably is operably coupled to a gas reservoir having a valve to control the intake of inert gas into the chamber. Multiple gas inlets (e.g., 202 302) and outlets (e.g., 204 304) can be utilized with the chambers herein. Means for circulating the gas within the pressurized chamber, such as through the use of one or more fans, are also readily contemplated herein. According to advantageous embodiments, the gas can be circulated evenly, or substantially so, to maintain uniform, or substantially uniform temperature and pneumatic pressure on the workload. FIG. 4B shows a close up view of how universal, or substantially universal, low pneumatic pressure on all sides of the workload maintains the 3-dimensional structure of the polystyrene beads. This process results in an end product having a constant, or substantially constant, density throughout, and thus having high structural strength. This is in contrast to FIG. 4A, which depicts prior art mechanical crushing that destroys the 3-dimensional structure of the polystyrene beads. Not only does the prior art method destroy the structural integrity of the polystyrene beads, it creates an end product having varied densities because utilizing physical crushing means prevents universal pressure on all sides of the workload, as the teachings herein do. An end product having varied densities is disadvantageous for the purposes herein and will often flake and have sections that will break away easily.

According to preferred embodiments, the teachings herein utilize a pressure of less than 1,000 psi to compress the EPS workload within the pressurized chamber. According to even more specific embodiments, the teachings herein can utilize a pressure selected from less than 500 psi, less than 464 psi, less than 100 psi, less than 50 psi, less than 30 psi, and 25 psi or less to compress the EPS workload within the pressurized chamber. Prior art compressed EPS can have an average weight of approximately 20 lbs/cubic foot. According to the methods provided herein the compressed polystyrene (CPS) advantageously can have a final average weight selected from the following: less than 0.5 lbs/cubic foot, less than 0.1 lbs/cubic foot, less than 0.075 lbs/cubic feet, or 0.0655 lbs/cubic foot, or approximately so.

The temperature and pressure is preferably held for a period of time such as to compress the EPS pieces, but not so much that it compromises the structural integrity of the EPS. For example, if the temperature is raised over 464° F., the structural integrity of the EPS workload will be compromised by melting. At this heat, the styrene will become brittle, and if slight pressure is applied, it will turn into a powder which is undesirable for the teachings herein. The pressure and heat are preferably applied for a period of time sufficient to apply universal, or substantially universal, pressure and temperature on the workload. This prevents different workload pieces having different pressures and temperatures applied and helps achieve uniformity in the resulting product by avoiding variance in the treatment. As one example, the temperature and pressure can be applied or held for 15 minutes. Depending on the pressure chamber utilized and heat and pressure means, the hold time can be between 1-30 minutes, but preferably 12-17 minutes, or substantially so. The pressure and heat can be applied continuously or intermittently according to various embodiments.

Cool-down at the end of the process cycle can entail a means of extracting heat from the pressurized chamber. The variables involved in a controlled cool-down will depend upon the workload being processed and the end product desired. Means for cooling down the workload can involve cooling elements, heat extraction, the use of cold air/gas, and creating a partial vacuum within the chamber. Pressurized chambers described herein advantageously include means for removing trapped gas/air within the chamber after pressurization and heating. Outlets (e.g., 204 and 304) operably coupled to the chamber are expressly contemplated herein. More specifically, it is contemplated to utilize pressure chambers having means for creating a partial vacuum within the pressurized chamber, such as to lower the internal pressure below atmospheric pressure. Examples of preferred means for creating a partial vacuum include vacuum pumps and the like. Vacuum pumps can be used to suck air, steam, or gas from the pressurized chamber after heating and pressurization. According to advantageous embodiments the chamber pressure is reduced to −0.5 Torr, or substantially so.

After creating the partial vacuum, it is preferred to raise the atmospheric pressure within the pressurized chamber utilizing any of the heating/pressurization means described above for the initial heating/pressurization step described above. For example, air, gas, or steam can be delivered within the pressurized chamber to bring the internal chamber back to atmospheric pressure, or substantially so. More specifically, air or gas between 90°-130° F. can be delivered to the chamber and circulated as desired.

The EPS workload can then be removed from the pressurized chamber as compressed polystyrene or “CPS” and further processed as desired. Pressure chambers herein can include rollers, or other transport means, such as shown in FIG. 7 to facilitate loading and unloading the workload and CPS respectively. During post-compression processing, it can be advantageous to apply or maintain light pressure on the CPS to maintain its size, shape, and texture by preventing mishandling. Examples of means to apply or maintain pressure on the CPS include horizontal and vertical guide wheels and/or pressure rollers. Heat can also be provided on the CPS through a variety of means, such as utilizing heating elements, heated gas, and/or steam. It can also be advantageous to utilize a conveyor belt to automate the process while the CPS is further processed, depending on the end product desired.

One post-compression modification can include the application of a fire retardant to reduce the flammability or combustibility of the end product. Any suitable fire retardant can be applied to form a protective layer that prevents or hinders the CPS from burning. More specifically, the fire resistant chemical sodium silicate can be applied to the CPS. The fire retardant can be applied to the CPS using any suitable means, such as by spraying, rollers, or dipping. As one example the top of a sheet of CPS can be coated with a thin layer of sodium silicate. The layer can be less than 0.1″, and more preferably about 0.0625″. The sodium silicate solution can made be to any suitable diluted ratio, such as 1 to 0.25 of deionized water. After the first coat of fire retardant is applied to the CPS, a layer of heavy paper can then be applied on top. Any suitable type of heavy paper can be applied; as one example a coarse 20 lb. paper can be pressed onto the wet coated first layer of fire retardant, or otherwise adhered. The CPS can be cured using any suitable heat range or source until the surface is dry, such as an oven using temperatures between 70°-90° F. If desired, a second, third, or more layers of fire retardant can also be added to the first coating and the paper. As one example, the top of the paper can be coated with a thicker layer of sodium silicate, such as more than 0.1″, and more preferably 0.125″, at a diluted ratio of 1 to 0.125 of deionized water. The second, third, or more layers of fire retardant can likewise be cured to dry as discussed above. Any excess paper and/or edges of the CPS can be trimmed, routered, or otherwise cut to achieve the desired size and shape of the end product, including a stile or rail shape.

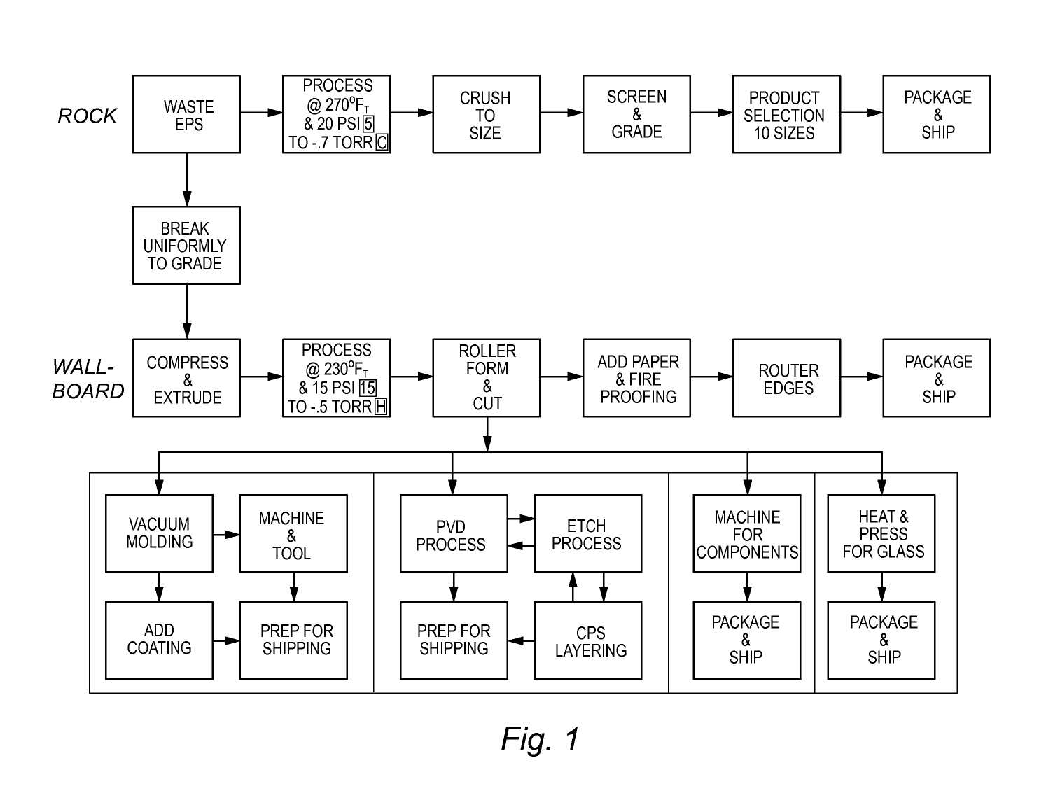

As shown in FIG. 1, additional or alternative post-compression modifications can also be performed after the CPS is removed from the pressurized chamber. These modifications non-exclusively include: vacuum molding or forming, physical vapor deposition (PVD), machining, insulating, press-brake forming, and bore and glazing. With respect to vacuum molding, the CPS can be placed over a single surface mold and a vacuum suctioning can be applied between the mold surface and the CPS such that the CPS sheet takes the form of the mold. With PVD, a vaporized material such as metal can be vacuum deposited onto the CPS as a thin film by condensation. A variety of etching and layering methods utilizing templates can be used in conjunction with the PVD to achieve the final product. Anti-bacterial and Anti-mold chemicals can also be applied to the CPS. Additionally, CPS can be used as a base mold for casting metal parts. As an example CPS can be formed or shaped into the desired shape of the mold and then placed in the pressure chamber as described above. After compression, the shaped CPS could be coated in a liquid slurry that will harden to form the mold. During the casting process, the CPS can melt out. With respect to insulating, any suitable insulation can be applied to the CPS. As one example a polyester film, such as Biaxially-oriented polyethylene terephthalate, including aluminized polyester can be used as insulation on the CPS.

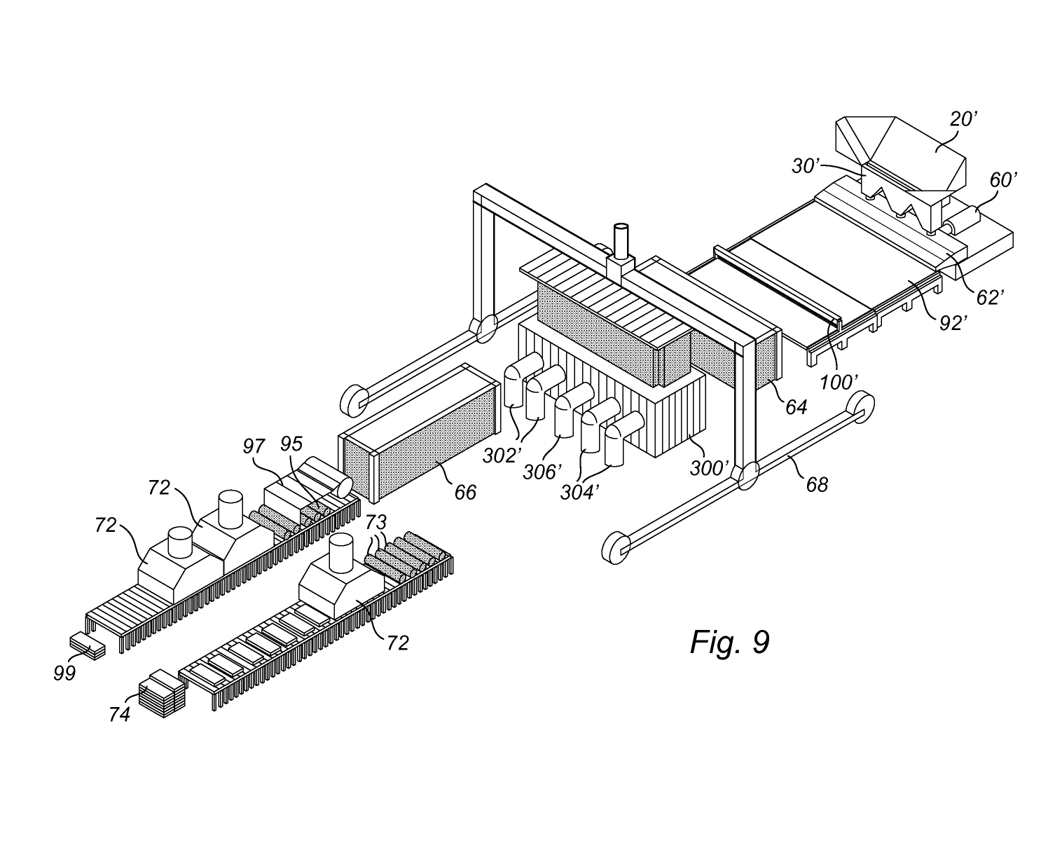

FIG. 9 shows an exemplary preferred system for processing EPS into CPS wallboard. FIG. 9 is merely exemplary, as certain processes and apparatuses within this system can be removed or altered based on the teachings above. EPS is placed into the hopper 20′ and the grinder 30′ breaks apart the EPS into chunks which are dropped into the extruder 62′ where an auger 60′ forces the chunks through a die having a cutout into a sheet. The sheet is placed onto the conveyor belt 92′ which directs the sheet to a platform having a raised cutting knife 100′ configured to cut the sheet into predetermined sizes. Cut sheets can be loaded onto racks 64 and loaded into the pressurized chamber 300′ using any suitable means, such as a mobile gantry crane 68. In this example, the racks 64 holding the EPS workload are top loaded into the pressurized chamber 300′ having intakes 302′, outlets 304′, and an emergency blow off 306′. After heat and pressure treatment within the pressurized chamber 300′, the resulting CPS can be placed in a holding area 66 and/or modified for final packaging. As one example sodium silicate can be applied using sealant rollers 95 and fire proof or retardant paper 97 can be applied to the CPS sheets. The CPS sheets can be cut to size and passed through drying hoods 72 to form CPS wallboard 99. As another example of post-compression modifications can be minimal, where the CPS is placed on rollers 73 which direct the sheets to a drying hood 72 and final packaging 74.

While described above as post-compression modifications, it is expressly noted that these modifications can also be performed where suitable before compression of the EPS within the pressurized chamber. For example, block EPS can be cut and shaped before being placed into the pressurized chamber. Regardless of when they are performed, the process steps described herein can be done manually or using an automated system, such as a computer controlled system.

### CPS Rock

CPS rock derived from EPS can be utilized for multiple purposes, non-exclusively including an aggregate in concrete, as filler for roadways (e.g., asphalt), as a decorative rock, which can be colored as desired. EPS is advantageous in being resistant to degradation from soil or other environmental elements and can easily maintain its strength and shape. CPS rock can be generated using similar methods to the CPS wallboard methods described above. Likewise, the same types of pressurized chambers 200 and 300 shown in FIGS. 2 and 3 and described above, can be utilized for these methods. Waste EPS or EPS broken down into chunks can be placed into the pressurized chamber to be compressed. Suitable heating and pressure means can be used to raise the temperature between 250°-462° F. and raise the internal pressure within the chamber to between 15-464 psi. This can be done for preferably less than 10 minutes, and more preferably between 3-7, or 4-6 minutes, such as 5 minutes. Afterwards the chamber pressure can be reduced, such as to −0.7 torr. After the partial vacuum is created, the internal chamber can be brought up to atmospheric pressure, using either cool or ambient gas, such as air. More specifically, it is preferred that the gas is below 70° F. substantially so. Afterwards, the CPS can be allowed to cool and removed from the pressurized chamber. The CPS can then be crushed using any type of crushing means, such as roller crushers or plates. According to certain embodiments, the EPS rock can be crushed to any chunk size, non-exclusively including sand consistency. Additionally, any pressure can be utilized with this step. The crushed CPS can then be screened for size using sieves, filters, or any suitable means.

All references listed herein are expressly incorporated by reference in their entireties. The invention may be embodied in other specific forms besides and beyond those described herein. The foregoing embodiments are therefore to be considered in all respects illustrative rather than limiting, and the scope of the invention is defined and limited only by the appended claims and their equivalents, rather than by the foregoing description.

1. A process for converting expanded polystyrene (EPS) into a compressed material, comprising:
a) placing an EPS workload into a pressurized chamber;
b) increasing the temperature within the chamber; and
c) increasing the pressure within the chamber by introducing a gaseous material into the chamber such that the pressure within the chamber does not exceed 500 psi to create a compressed polystyrene material from the EPS workload.

2. The process of claim 1, wherein the internal temperature within the pressurized chamber is raised to between 190°-250° F. and does not exceed 250° F.

3. The process of claim 2, wherein the internal pressure within the chamber is between 0.1-15 psi, such that it does not exceed 15 psi.

4. The process of claim 3, wherein the increased temperature and pressure are simultaneously held for between 5-30 minutes.

5. The process of claim 4, wherein the pressure in the chamber is lowered to −0.5 Torr, after holding the increased temperature and pressure.

6. The process of claim 1, where the EPS workload comprises EPS extruded waste EPS.

7. The process of claim 1, wherein the compressed polystyrene product has a weight of less than 0.5 lbs/cubic foot.

8. The process of claim 1, wherein the compressed polystyrene product undergoes post-compression modifications of papering and adding fire retardant materials.

9. The process of claim 1, wherein the compressed polystyrene product is vacuum molded.

10. The process of claim 1, wherein an insulative material is applied to the compressed polystyrene product.

11. The process of claim 1, wherein the compressed polystyrene product undergoes physical vapor deposition.

12. The process of claim 1, wherein the internal temperature within the pressurized chamber is raised to between 250-462° F., and does not exceed 462° F.

13. The process of claim 12, wherein the internal pressure within the chamber is between 15°-464° psi, and does not exceed 464° psi.

14. The process of claim 13, wherein the temperature and pressure are simultaneously held for under 10 minutes.

15. The process of claim 14, wherein the pressure in the chamber is lowered to −0.7 Torr, after holding the increased temperature and pressure.

16. The process of claim 15, wherein the compressed polystyrene product is crushed into chunks.

17. The process of claim 1, wherein the EPS workload is shaped into a mold prior to be being placed into the compression chamber.

18. The process of claim 17, wherein the compressed polystyrene product is coated in a liquid slurry that hardens to solidify the mold.

19. The process of claim 1, wherein the gaseous material is selected from the group consisting of an inert gas, steam, and air.

20. The process of claim 1, further comprising lowering the pressure within the chamber to below atmospheric pressure after increasing the temperature and pressure.
